(19) United States
(12) Patent Application Publication
(10) Pub. No.: US 2026/0293624 A1
(43) Pub. Date: Sep. 24, 2026

(54) APPARATUS WITH THICKNESS CONTROL MECHANISM AND METHODS FOR MANUFACTURING THE SAME

(71) Applicant: Micron Technology, Inc., Boise, ID (US)

(72) Inventors: Thomas A. Figura, Boise, ID (US); Andrew T. McDonald, Boise, ID (US); Sheng Wei Yang, Boise, ID (US)

(21) Appl. No.: 19/561,157

(22) Filed: Mar. 9, 2026

Related U.S. Application Data
(60) Provisional application No. 63/774,662, filed on Mar. 19, 2025.

(51) Int. Cl. H10P 90/00; H10W 10/00; H10W 10/10; H10W 10/17; H10B 12/00; H10P 52/00

(52) U.S. Cl. CPC H10P 90/1922; H10P 90/1914; H10W 10/014; H10W 10/061; H10W 10/17; H10W 10/181; H10B 12/00; H10P 52/00

(57) ABSTRACT

Disclosed herein are methods, apparatuses and systems including thickness control mechanisms. The thickness control mechanisms may correspond to electrical insulators deposited into trenches that are formed on a semiconductor substrate. After forming circuits on the semiconductor substrate, the substrate may be thinned on an opposing side until the thickness control mechanisms are exposed. Prior to thinning, the substrate can be attached to a carrier with a layer of insulative material disposed between the substrate and carrier. The attached structure may correspond to a silicon on insulator (SOI) structure.

### CROSS-REFERENCE TO RELATED APPLICATION(S)

The present application claims priority to U.S. Provisional Patent Application No. 63/774,662, filed March 19, 2025, the disclosure of which is incorporated herein by reference in its entirety.

### TECHNICAL FIELD

The disclosed embodiments relate to devices, and, in particular, to semiconductor devices with thickness control mechanism and methods for manufacturing the same.

### BACKGROUND

With technological advancements in semiconductor processing and increasing applications, the market is continuously looking for faster, more efficient, and smaller semiconductor devices. To meet the market demand, the semiconductor devices are being pushed to the limit. In view of the ever-increasing commercial competitive pressures, along with growing consumer expectations and the desire to differentiate products in the marketplace, it is increasingly desirable that answers be found to these problems. Additionally, the need to reduce costs, improve efficiencies and performance, and meet competitive pressures adds an even greater pressure to find answers to these problems.

In an effort to increase the operating speed and/or the circuit density, devices have started arranging or stacking circuits along a vertical direction. FIG. 1 is a side view of a silicon-on-insulator (SOI) structure 100 (e.g., a SOI wafer) that may be used to increase the circuit density of a subsequently formed device. The SOI structure 100 includes an insulator layer 104 disposed between semiconductor layers 102 and 106 (i.e., a top wafer portion 102 and a bottom wafer portion 106). The insulator layer 104 includes an electrical insulator, such as silicon dioxide or sapphire. The top wafer portion 102 may be used to form circuit components, and the bottom wafer portion 106 may correspond to a handle wafer.

Conventional SOI structure 100, such as a SiO2 wafer, may be manufactured through a separation by implantation of oxygen (SIMOX) method that uses an oxygen implantation process and a high temperature annealing process that buries or forms the insulator layer 104 within a semiconductor substrate. Alternatively, the SOI structure 100 may be formed through wafer bonding, such as by directly bonding oxidized silicon with a second substrate. Another manufacturing method includes a seed method that directly grows the top wafer portion 102 on or from the insulator layer 104.

While the SOI structure 100 provides various improvements, such as controlled thickness, planar surfaces, and reduction in parasitic capacitance, the manufacturing cost is significantly higher than that of a conventional semiconductor substrate. Accordingly, the use of the SOI structure 100 in place of the conventional substrate greatly increases the overall manufacturing cost of an apparatus. As an example, using the conventional SOI structure 100 to manufacture each of the core memory dies within a High-Bandwidth Memory (HBM) device would increase the manufacturing cost in direct proportion to the targeted stack height and the corresponding memory capacity.

### BRIEF DESCRIPTION OF THE DRAWINGS

The foregoing and other objects, features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure.

FIG. 1 is a side view of a silicon-on-insulator (SOI) structure.

FIG. 2 is a cross-sectional view of a first structure formed during a manufacturing process in accordance with an embodiment of the present technology.

FIG. 3 is a cross-sectional view of a second structure formed during a manufacturing process in accordance with an embodiment of the present technology.

FIG. 4 is a cross-sectional view of a third structure formed during a manufacturing process in accordance with an embodiment of the present technology.

FIG. 5 is a cross-sectional view of a fourth structure formed during a manufacturing process in accordance with an embodiment of the present technology.

FIG. 6A is a cross-sectional view of a fifth structure formed during a manufacturing process in accordance with an embodiment of the present technology.

FIG. 6B is a top view of example arrangements of thickness controllers in accordance with an embodiment of the present technology.

FIG. 7 is a cross-sectional view of a sixth structure formed during a manufacturing process in accordance with an embodiment of the present technology.

FIG. 8 is a block diagram of an apparatus in accordance with an embodiment of the present technology.

FIG. 9 is a flow diagram illustrating an example method of manufacturing an apparatus in accordance with an embodiment of the present technology.

FIG. 10 is a schematic view of a system that includes an apparatus in accordance with an embodiment of the present technology.

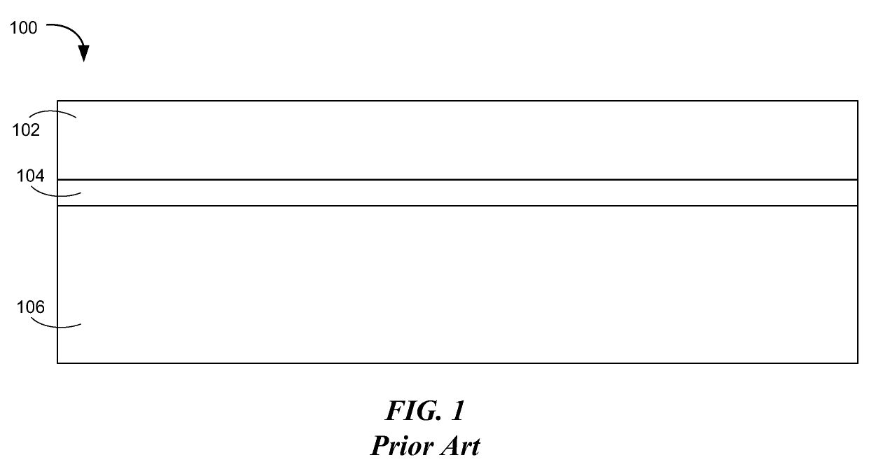

### DETAILED DESCRIPTION

As described in greater detail below, the technology disclosed herein relates to an apparatus, such as semiconductor devices, related methods, etc., manufactured using a thickness control mechanism. The thickness control mechanism can include electrically insulative fillers within deep trenches. As an illustrative example, a manufacturing process can start with a semiconductor wafer (e.g., a solid and uniform silicon wafer instead of a SOI wafer). A first set of functional circuitry (e.g., an array for a memory) can be formed on or through a reference surface at designated regions or locations. Trenches may be formed adjacent to or between the designated regions. The trenches can have a target depth below the reference surface. The trenches can be filled with an electrical insulator, such as an oxide material, that can further form a layer over the reference surface. The method can include forming an attaching layer (e.g., a SIOC layer) over the electrical insulator layer.

The resulting substrate can be flipped and attached over a semiconductor carrier wafer having its own attaching layer. Thus, the combined structure can have an electrical insulator layer disposed between semiconductor wafers/layers, similar to the commercially available SOI wafers. Subsequently, the backside of the flipped top wafer can be thinned until the insulative fillers are exposed. As a result, the top wafer portion can have a thickness corresponding to the target depth. The combined wafer can be further processed, such as by forming circuitry (e.g., access circuitry) on the thinned backside, wafer bonding to another processed wafer, singulation, and/or the like, to manufacture a semiconductor device or die. The resulting die can have seemingly non-functional bodies or columns of insulative material having uniform height disposed between the circuit regions.

The manufacturing method that includes forming the thickness controllers in the top wafer portion, forming the insulative layer, attaching the top wafer portion to the carrier wafer, and then thinning based on exposing the thickness controllers can effectively produce the SOI wafer structure with significantly lower cost (e.g., by a factor of 10 or more). Forming the thickness controller can leverage existing processes for forming trenches and forming/filling insulator or oxide material. Accordingly, a device manufacturer can effectively self-manufacture the SOI wafer using readily available solid semiconductor wafers instead of purchasing a specialty-made SOI wafer. Additionally, using the thickness controllers, the manufacturing method can produce thinned wafers that have uniform planar surfaces (e.g., with thickness variation being limited to tens of nanometers or less than 10 nanometers) across lateral directions.

### Example Manufacturing Phases

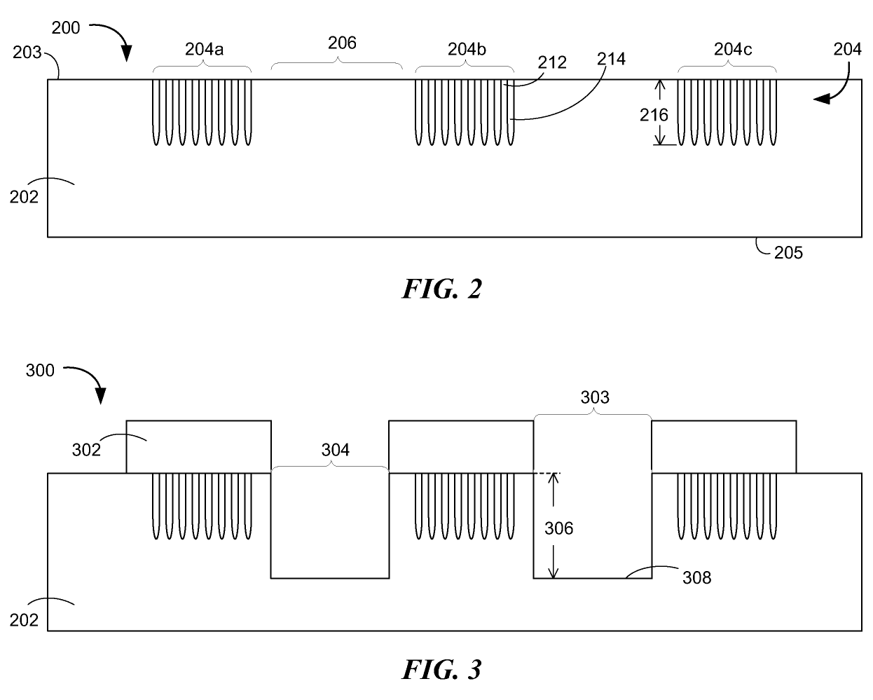

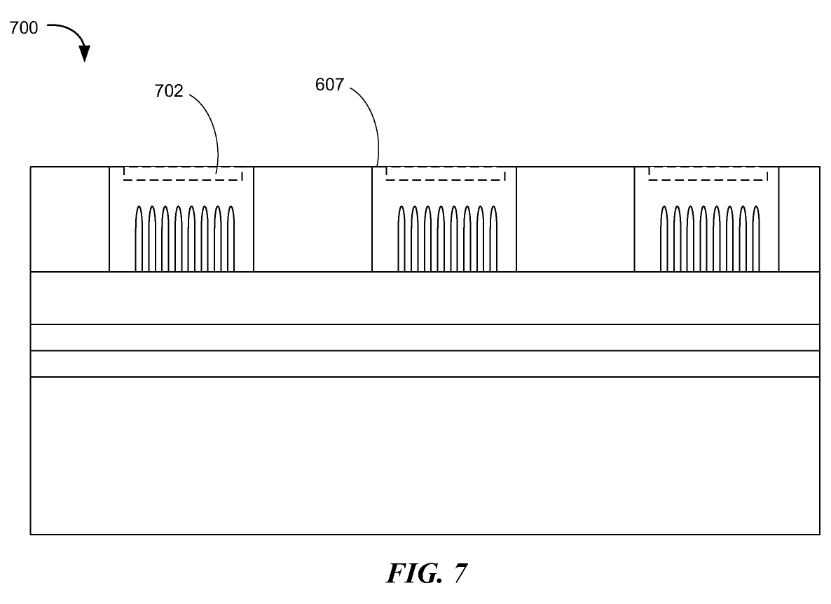

FIG. 2 – FIG. 7 illustrate various example stages that occur and corresponding structures that are formed during a manufacturing process in accordance with an embodiment of the present technology. For the illustrated example, FIG. 2 is a cross-sectional view of a first structure 200 formed during a manufacturing process in accordance with an embodiment of the present technology. The first structure 200 can correspond to a result of providing a semiconductor substrate (e.g., a wafer, such as a solid/uniform silicon wafer) and then forming functional circuitry 204 on or through a reference surface 203 (e.g., an active or a front side) that is opposite a back surface 205. The structure 200 can have separating regions 206 between the groupings of the functional circuitry 204.

In some embodiments, the functional circuitry 204 can include collections or sets of memory storage cells, such as arrays. Each grouping of the functional circuitry 204, such as circuit groupings 204a, 204b, and 204c, can be formed on device regions 212 (e.g., mesas) separated or defined by local trenches 214. The local trenches 214 can reach to a circuit depth 216 below the reference surface 203. Stated differently, the functional circuitry 204 (e.g., the corresponding doped regions, the current channels, and/or the like) can be located within the circuit depth 216 relative to the reference surface 203.

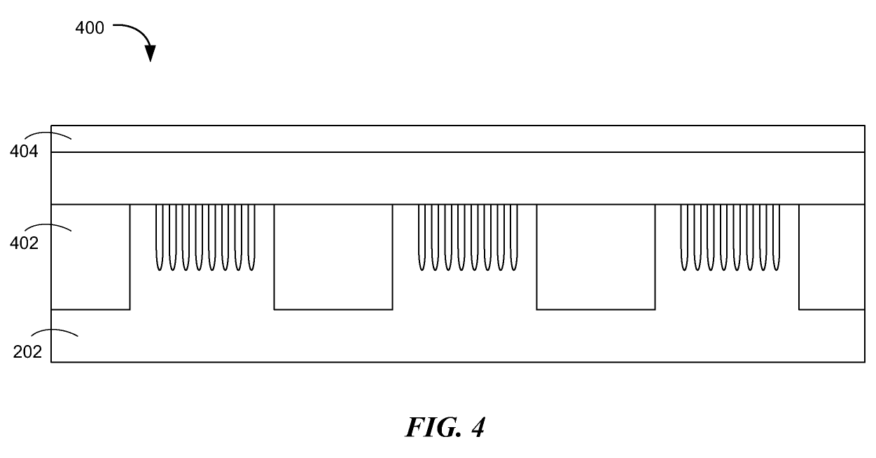

FIG. 3 is a cross-sectional view of a second structure 300 formed during a manufacturing process in accordance with an embodiment of the present technology. The second structure 300 can correspond to a result of forming one or more masks 302 and then etching through openings on the masks 302 to form deep trenches 304 (also called marker trenches). The deep trenches 304 can be formed in the separating regions 206 of FIG. 2. In other words, the masks 302 can cover the functional circuitry 204 of FIG. 2 and expose portions of the reference surface 203 at targeted locations over the separating regions 206. In some embodiments, the deep trenches 304 can be formed by an etching process, such as chemical etch, dry etch, laser etch, and/or the like. The deep trenches 304 can have a trench depth 306 that is deeper than the circuit depth 216 of FIG. 2. Stated differently, the bottom surface in the deep trenches 304 can be further below or beyond the bottom portion of the local trenches 214 of FIG. 2 relative to the reference surface 203. The trench depth 306 can further correspond to a targeted thickness for the device/wafer to be formed from the semiconductor substrate 202 of FIG. 2.

The deep trenches 304 can have a bottom portion 308 that includes a flat surface. The flat/planar aspect of the bottom portion 308 can correspond to a trench top open width and/or a width of the mask opening 303. As described below, the mask opening 303 can have one or more dimensions, shapes, and/or relative arrangements that correspond to the bottom portion 308 as well as cross-sectional shapes and relative arrangements of the thickness controllers (e.g., the filler material within the deep trenches 304 that serve as etch stop triggers for establishing a planar surface).

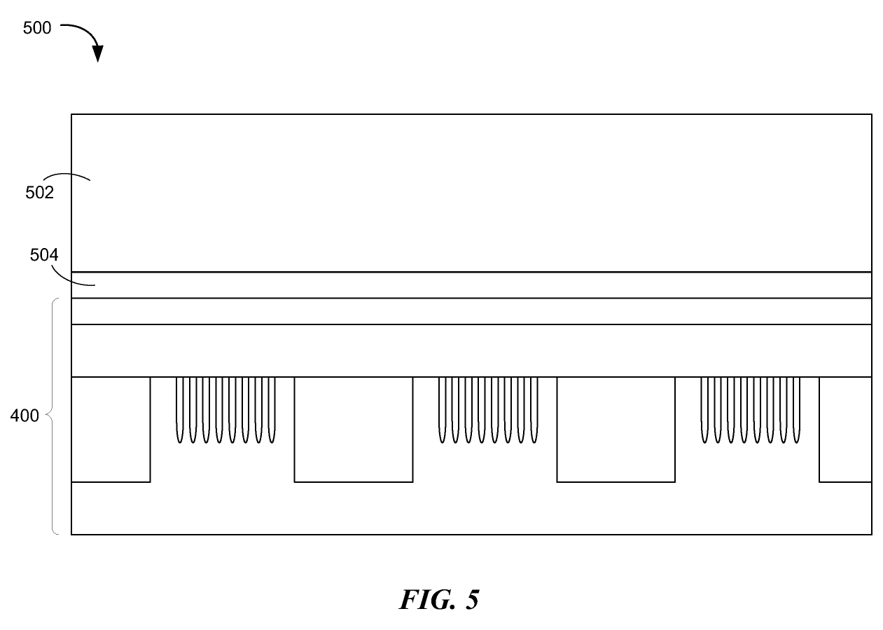

FIG. 4 is a cross-sectional view of a third structure 400 formed during a manufacturing process in accordance with an embodiment of the present technology. The third structure 400 can correspond to a result of depositing one or more electrically insulative materials on the second structure 300 of FIG. 3. For example, the manufacturing method can include depositing oxide material to as filler material 402 within the deep trenches 304 of FIG. 3. The oxide material can further form a layer over the reference surface 203 of FIG. 2.

The method can further include depositing and forming a first attaching layer 404 over the reference surface 203 and/or the filler material 402 (e.g., the corresponding layer and/or the filler within the deep trenches). In some embodiments, the deposited attaching layer 404 can include a silicon oxycarbide (SIOC) layer.

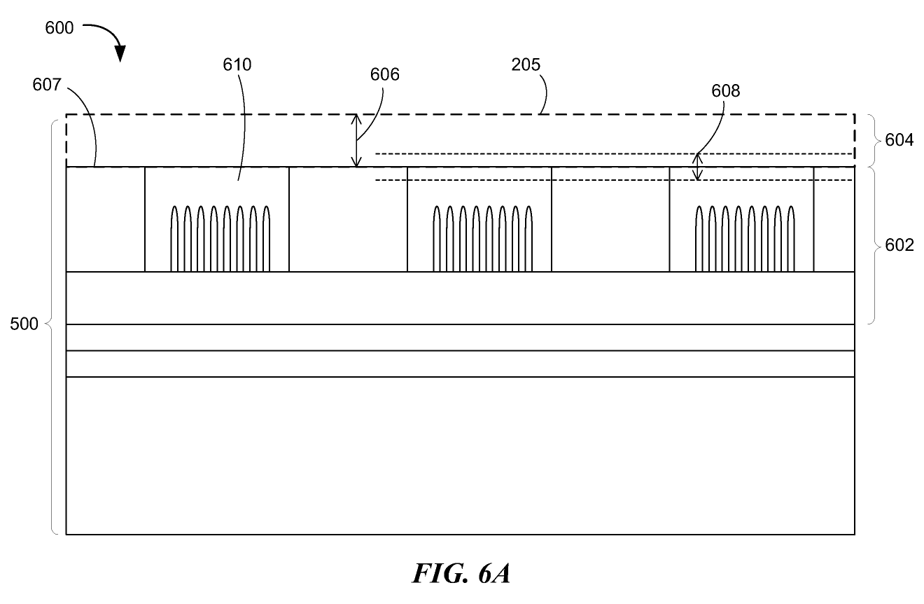

FIG. 5 is a cross-sectional view of a fourth structure 500 formed during a manufacturing process in accordance with an embodiment of the present technology. The fourth structure 500 can correspond to a result of attaching the third structure 400 to a carrier wafer 502 (e.g., a solid or uniform semiconductor wafer). For example, the carrier wafer 502 can have a second attaching layer 504 (e.g., a separate SIOC layer) that is attached to the first attaching layer 404 of FIG. 4.

Further, the fourth structure 500 can be structurally parallel to a conventional SOI, but manufactured using existing processes that are simpler and cheaper than targeted SOI manufacturing processes. For example, the fourth structure 500 can have the insulator material, such as the filler material 402 of FIG. 4, forming a layer disposed between two semiconductor wafers. The structure 500 can be further processed as described below to create a device having a thinned and targeted thickness that corresponds to a uniform planar surface.

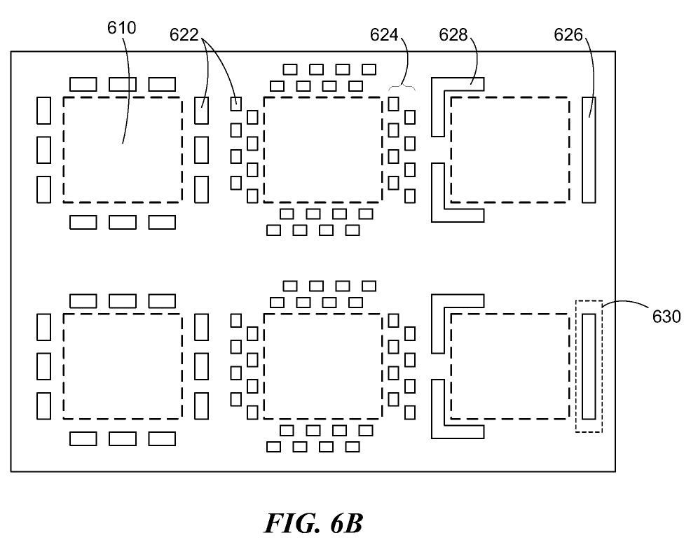

FIG. 6A is a cross-sectional view of a fifth structure 600 formed during a manufacturing process in accordance with an embodiment of the present technology. The fifth structure 600 can correspond to the result of flipping the structure 500 and then thinning the third structure 400 of FIG. 4 to form a targeted apparatus 602. For example, the method can include removing a back portion 604 (e.g., material at and/or near the back surface 205 of FIG. 2) from the semiconductor substrate 202 of FIG. 2 within the third structure 400. The back portion 604 can be removed through one or more an etching process, a cutting process, a polishing process, and/or the like.

The removed back portion 604 can correspond to a removal depth 606 that corresponds to a difference between the original thickness of the substrate 202 and the trench depth 306 of FIG. 3 (e.g., the targeted depth of the overall device). In some embodiments, the trench depth 306 can be 100 microns or less.

To achieve the targeted removal depth 606, the method can include checking for the filler material 402 in the deep trenches 304 of FIG. 3 and stopping when the deep trenches 304 become exposed while removing the back portion 604. Accordingly, the manufacturing method can establish a post-thinning surface 607 that is planar across the remaining part of the substrate 202 (e.g., remaining silicon 610 now above the device region 212 of FIG. 2) and the filler material 402 that has been exposed. Using the exposer of the filler material 402 as a cue across the lateral dimensions of the substrate during the removal process, the manufacturing method can establish an effectively planar post-thinning surface 607 that satisfies a planar uniformity range 608. In other words, the thickness of the targeted apparatus 602 at different locations can be effectively uniform and within the planar uniformity range 608 relative to other points and/or the trench depth 306. The planar uniformity range 608 can be within tens of nano meters or less (i.e., less than 10 nanometers). In comparison, the removal depth can be in the range of hundreds of nanometers.

FIG. 6B is a top view of example arrangements of thickness controllers (e.g., the filler material 402 of FIG. 4 that has been exposed after the removal process) in accordance with an embodiment of the present technology. The top view shown in FIG. 6B can illustrate example cross-sectional shapes and/or arrangements of the filler material 402 and the corresponding deep trenches 304 of FIG. 3 along lateral directions.

In some embodiments, the filler material 402 can have island shapes 622 such that one or more lateral dimensions of the filler material 402 is less than half (e.g., 33% or less) of the parallel lateral dimension of the remaining silicon 610 of FIG. 6A. The island shapes 622 can have cross-sectional shapes that correspond to rectangles, squares, ovals, circles, other polygonal shapes, or user-specified shapes that correspond to the shape of the openings in the mask 302 of FIG. 3. Further the cross-sectional shapes can have rounded corners.

Two or more of the filler material 402 having the island shapes 622 can be arranged along a line parallel to and within a threshold distance from a peripheral edge of the remaining silicon 610. The linearly arranged islands of the filler material 402 can be separated by a predetermined separation distance. Additionally, the islands of the filler material 402 can be arranged according to multi-row arrangement 624, such as for multiple columns/rows adjacent to one or each of the peripheral edge of the remaining silicon 610.

In some embodiments, the cross-sectional shape of the filler material 402 can be different or larger than the island shapes 622. For example, the filler material 402 can have a lengthened shape 626 that has a dimension that extends more in a column/row shape. The lengthened shape 626 can have a dimension that is parallel to a peripheral edge of the remaining silicon area 610 and greater than an orthogonal dimension by a factor of 2 or more. In other embodiments, the cross-sectional shape of the filler material 402 can have a multi-directional shape 628, such as for continuously extending around a corner.

The cross-sectional shape and arrangements can be controlled to provide a targeted insulative effect while improving the detectability during the thinning process. For example, the shapes and arrangements of the filler material 402 can be controlled according to a targeted density of the filler material 402 relative to the semiconductor material within a marking area 630 adjacent to the corresponding edge of the remaining silicon area 610.

FIG. 7 is a cross-sectional view of a sixth structure 700 formed during a manufacturing process in accordance with an embodiment of the present technology. The sixth structure 700 can be a result of forming opposite-side circuits 702 on or through the post-thinning surface 607. The opposite-side circuits 702 can be formed within the remaining silicon 610 and vertically displaced from the functional circuitry 204 of FIG. 2. In some embodiments, the functional circuitry 204 can include storage cells or arrays, and the opposite-side circuits 702 can include access devices that store charges into the memory cells and/or read voltage levels of the charges stored in the memory cells.

While not shown, the manufacturing method can further process the sixth structure 700 to produce a targeted apparatus. For example, additional circuitry and access portions can be formed as back-end of line (BEOL) structures over the opposite-side circuits 702. Additionally, a portion of the carrier wafer 502 may be removed or thinned, thereby maintaining the layer of filler material between two planar semiconductor structures/wafers. Moreover, the sixth structure 700 or a processed result thereof may be wafer bonded to other wafer structures. The sixth structure 700 or a processed result thereof can be singulated to form the targeted apparatus, such as a semiconductor die or an integrated package.

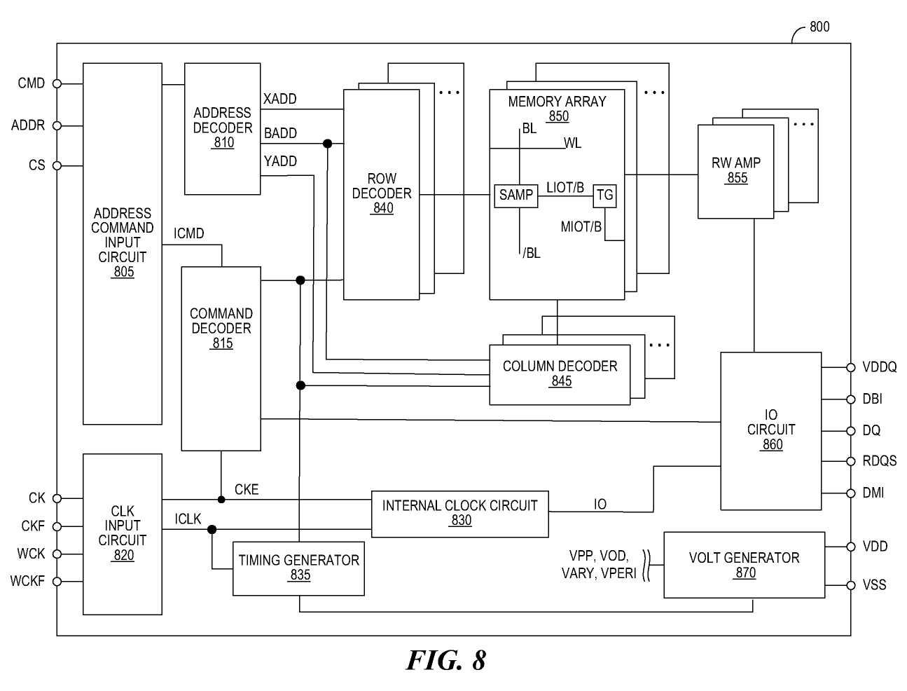

In some embodiments, the targeted apparatus can include a memory device, such as a DRAM. FIG. 8 is a block diagram of an apparatus (e.g., a memory device 800 including a semiconductor die assembly, including a 3DI device or a die-stacked package) in accordance with an embodiment of the present technology. For example, the memory 800 can include a DRAM (e.g., DDR4 DRAM, DDR5 DRAM, LP DRAM, HBM DRAM, etc.), or a portion thereof that includes one or more dies/chips. In some embodiments, the memory 800 can include synchronous DRAM (SDRAM) of DDR type integrated on a single semiconductor chip.

The memory 800 may include an array of memory cells, such as memory array 850. In some embodiments, the functional circuitry 204 of FIG. 2 can correspond to the memory array 850. The memory array 850 may include a plurality of banks (e.g., banks 0–15), and each bank may include a plurality of word lines (WL), a plurality of bit lines (BL), and a plurality of memory cells arranged at intersections of the word lines and the bit lines. Memory cells can include any one of a number of different memory media types, including capacitive, magnetoresistive, ferroelectric, phase change, or the like. The selection of a word line WL may be performed by a row decoder 840, and the selection of a bit line BL may be performed by a column decoder 845. Sense amplifiers (SAMP) may be provided for corresponding bit lines BL and connected to at least one respective local I/O line pair (LIOT/B), which may in turn be coupled to at least respective one main I/O line pair (MIOT/B), via transfer gates (TG), which can function as switches. The memory array 850 may also include plate lines and corresponding circuitry for managing their operation.

The memory 800 may employ a plurality of external terminals that include command and address terminals coupled to a command bus and an address bus to receive command signals (CMD) and address signals (ADDR), respectively. The memory 800 may further include a chip select terminal to receive a chip select signal (CS), clock terminals to receive clock signals CK and CKF, data clock terminals to receive data clock signals WCK and WCKF, data terminals DQ, RDQS, DBI, and DMI, power supply terminals VDD, VSS, and VDDQ.

The command terminals and address terminals may be supplied with an address signal and a bank address signal (not shown in FIG. 8) from outside. The address signal and the bank address signal supplied to the address terminals can be transferred, via a command/address input circuit 805, to an address decoder 810. The address decoder 810 can receive the address signals and supply a decoded row address signal (XADD) to the row decoder 840, and a decoded column address signal (YADD) to the column decoder 845. The address decoder 810 can also receive the bank address signal and supply the bank address signal to both the row decoder 840 and the column decoder 845.

The command and address terminals may be supplied with command signals (CMD), address signals (ADDR), and chip select signals (CS), from a controller. The command signals may represent various memory commands from the memory controller (e.g., including access commands, which can include read commands and write commands). The chip select signal may be used to select the memory 800 to respond to commands and addresses provided to the command and address terminals. When an active chip select signal is provided to the memory 800, the commands and addresses can be decoded and memory operations can be performed. The command signals may be provided as internal command signals ICMD to a command decoder 815 via the command/address input circuit 805. The command decoder 815 may include circuits to decode the internal command signals ICMD to generate various internal signals and commands for performing memory operations, for example, a row command signal to select a word line and a column command signal to select a bit line.

Read data can be read from memory cells in the memory array 850 designated by row address (e.g., address provided with an active command) and column address (e.g., address provided with the read). The read command may be received by the command decoder 815, which can provide internal commands to input/output circuit 860 so that read data can be output from the data terminals DQ, RDQS, DBI, and DMI via read/write amplifiers 855 and the input/output circuit 860 according to the RDQS clock signals. The read data may be provided at a time defined by read latency information RL that can be programmed in the memory 800, for example, in a mode register (not shown in FIG. 8). The read latency information RL can be defined in terms of clock cycles of the CK clock signal. For example, the read latency information RL can be a number of clock cycles of the CK signal after the read command is received by the memory 800 when the associated read data is provided.

Write data can be supplied to the data terminals DQ, DBI, and DMI according to the WCK and WCKF clock signals. The write command may be received by the command decoder 815, which can provide internal commands to the input/output circuit 860 so that the write data can be received by data receivers in the input/output circuit 860, and supplied via the input/output circuit 860 and the read/write amplifiers 855 to the memory array 850. The write data may be written in the memory cell designated by the row address and the column address. The write data may be provided to the data terminals at a time that is defined by write latency WL information. The write latency WL information can be programmed in the memory 800, for example, in the mode register (not shown in FIG. 8). The write latency WL information can be defined in terms of clock cycles of the CK clock signal. For example, the write latency information WL can be a number of clock cycles of the CK signal after the write command is received by the memory 800 when the associated write data is received.

The power supply terminals may be supplied with power supply potentials VDD and VSS. These power supply potentials VDD and VSS can be supplied to an internal voltage generator circuit 870. The internal voltage generator circuit 870 can generate various internal potentials VPP, VOD, VARY, VPERI, and the like based on the power supply potentials VDD and VSS. The internal potential VPP can be used in the row decoder 840, the internal potentials VOD and VARY can be used in the sense amplifiers included in the memory array 850, and the internal potential VPERI can be used in many other circuit blocks.

The power supply terminal may also be supplied with power supply potential VDDQ. The power supply potential VDDQ can be supplied to the input/output circuit 860 together with the power supply potential VSS. The power supply potential VDDQ can be the same potential as the power supply potential VDD in an embodiment of the present technology. The power supply potential VDDQ can be a different potential from the power supply potential VDD in another embodiment of the present technology. However, the dedicated power supply potential VDDQ can be used for the input/output circuit 860 so that power supply noise generated by the input/output circuit 860 does not propagate to the other circuit blocks.

The clock terminals and data clock terminals may be supplied with external clock signals and complementary external clock signals. The external clock signals CK, CKF, WCK, WCKF can be supplied to a clock input circuit 820. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 820 can receive the external clock signals. For example, when enabled by a clock/enable signal from the command decoder 815, an input buffer can receive the clock/enable signals. The clock input circuit 820 can receive the external clock signals to generate internal clock signals ICLK. The internal clock signals ICLK can be supplied to an internal clock circuit 830. The internal clock circuit 830 can provide various phase and frequency controlled internal clock signals based on the received internal clock signals ICLK and a clock enable (not shown in FIG. 8) from the command/address input circuit 805. For example, the internal clock circuit 830 can include a clock path (not shown in FIG. 8) that receives the internal clock signal ICLK and provides various clock signals to the command decoder 815. The internal clock circuit 830 can further provide input/output (IO) clock signals. The IO clock signals can be supplied to the input/output circuit 860 and can be used as a timing signal for determining an output timing of read data and the input timing of write data. The IO clock signals can be provided at multiple clock frequencies so that data can be output from and input to the memory 800 at different data rates. A higher clock frequency may be desirable when high memory speed is desired. A lower clock frequency may be desirable when lower power consumption is desired. The internal clock signals ICLK can also be supplied to a timing generator and thus various internal clock signals can be generated.

### Manufacturing Flow

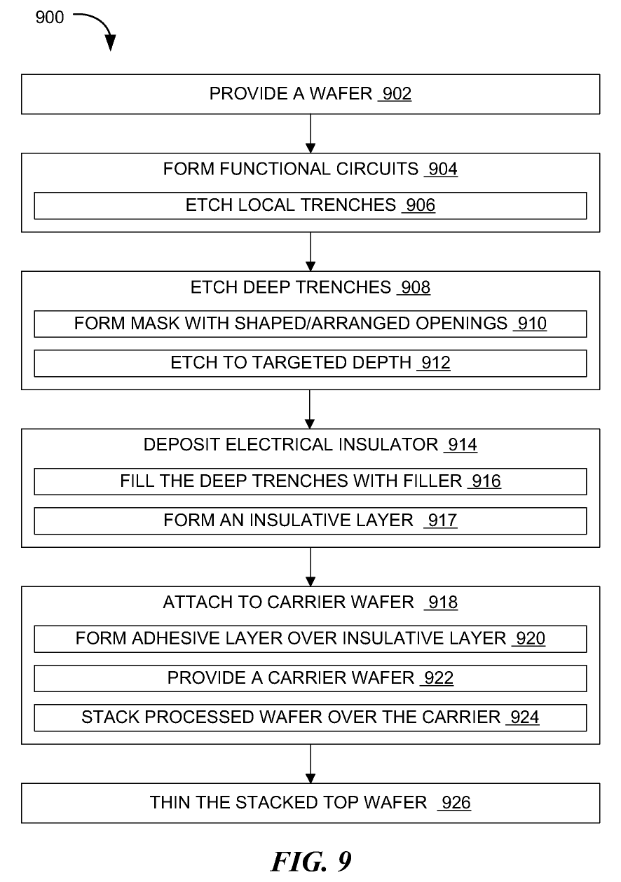

FIG. 9 is a flow diagram illustrating an example method 900 of manufacturing an apparatus (e.g., one or more of the structures 200-700 of corresponding FIGS. 2-7 and/or the memory 800 of FIG. 8) in accordance with an embodiment of the present technology. The method 900 can be for manufacturing the apparatus that includes the features and benefits of the SOI wafer using solid/uniform semiconductor wafers. Further, the method 900 can include forming circuitry on an intermediate structure that can be further processed to form a structure equivalent to the SOI wafer. In other words, the method 900 can include forming circuits before and in the process of forming a structure equivalent to the SOI wafer instead of starting with the SOI wafer and forming circuits thereon. The method 900 can correspond to processing phases associated with FIGS. 2-7 described above.

As shown in block 902, the method 900 can include providing a semiconductor wafer, such as the semiconductor substrate 202 of FIG. 2. The provided wafer can be a solid wafer with the semiconductor material being uniform throughout the body of the wafer. For example, the provided wafer can be a silicon wafer without prefabricated or preprocessed layers therein.

The method 900 can further include forming functional circuits (the functional circuitry 204 of FIG. 2), as shown in block 904. The functional circuits can be formed on a first or a reference side of the wafer through various manufacturing steps, such as masking, doping, connecting, etc. At block 906, the method can include etching local trenches. For example, the local trenches 214 of FIG. 2 can be formed along with the functional circuitry 204.

After forming the functional circuits, the method 900 can include etching deep trenches (e.g., the marker trenches 304 of FIG. 3) as shown in block 908. Etching the deep trenches can include forming masks (e.g., the mask 302 of FIG. 3) with shaped/arranged openings (e.g., the mask openings 303 of FIG. 3) as shown in block 910 and then etching through the openings to the targeted depth as shown in block 912. The resulting structure can correspond to the second structure 300 of FIG. 3.

At block 914, the method 900 can include depositing or forming one or more electrical insulators on the processed side (e.g., oxide material), such as covering the functional circuits. Depositing the electrical insulator(s) can correspond to filling the deep trenches with the filler material (e.g., the filler material 402), as shown at block 916, and forming an insulative layer over the processed side, as shown at block 917. The resulting structure can correspond to the third structure 400 of FIG. 4 or a portion thereof.

At block 918, the resulting structure can be attached to a carrier wafer (e.g., the carrier wafer 502 of FIG. 5). In some embodiments, attaching the processed wafer (e.g., the third structure 400) to the carrier wafer can include forming an adhesive layer (e.g., the first attaching layer 404 of FIG. 4) over the insulative layer of the processed wafer, as shown in block 920. At block 920, a carrier wafer, such as a separate semiconductor wafer, can be provided. The carrier wafer can further have an adhesive layer (e.g., the second attaching layer 504 of FIG. 5). At block 924, the processed wafer can be stacked over the carrier wafer. The wafers can be positioned to have the adhesive layers face each other, such as with the carrier wafer on the bottom and the processed wafer flipped and over the carrier wafer. The two wafers can be pressed, and the adhesive layers can bond the structures together. The resulting structure can correspond to the fourth structure 500 of FIG. 5 and have a similar structure as the SOI.

At block 926, the method 900 can include thinning the stacked top wafer. The resulting structure can correspond to the fifth structure 600 of FIG. 6. As described above, the thinning process can remove or etch away a back portion of the third structure 400 (e.g., the removed portion 604 of FIG. 6). The thinning process can continue until the filler material 402 in the marker trenches 304 are exposed. In other words, exposing the bottom planar portion of the filler material 402 within the trenches can serve as a trigger for stopping the thinning process. Accordingly, the remaining portions of the third structure 400 can have the targeted thickness that corresponds to the trench depth 306 of FIG. 3. Moreover, stopping the thinning process according to exposing the filler material 402 can establish the planar post-thinning surface 607 of FIG. 6 that is within the planar uniformity range 608 of FIG. 6, which is measured in magnitudes of many orders (e.g., 1/100 or less) than the removal depth 606 of FIG. 6.

### Overall System

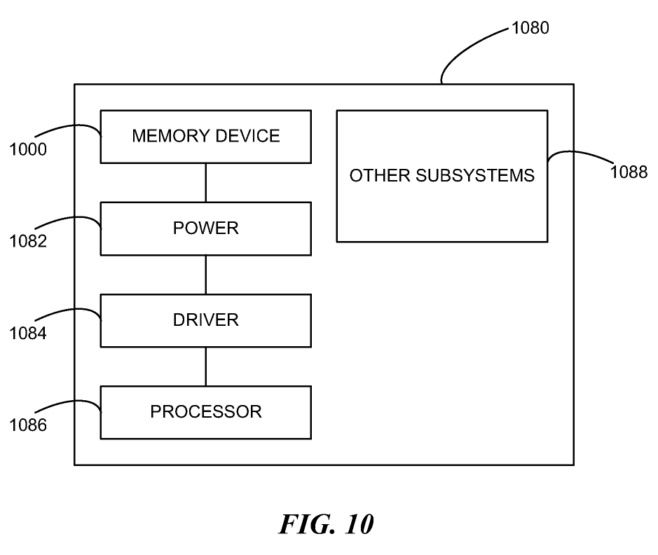

FIG. 10 is a schematic view of a system that includes an apparatus in accordance with embodiments of the present technology. Any one of the foregoing apparatuses (e.g., memory devices) described above with reference to FIGS. 2-9 can be incorporated into any of a myriad of larger and/or more complex systems, a representative example of which is system 1080 shown schematically in FIG. 10. The system 1080 can include a memory device 1000, a power source 1082, a driver 1084, a processor 1086, and/or other subsystems or components 1088. The memory device 1000 can include features generally similar to those of the apparatus described above with reference to one or more of the FIGS, and can therefore include various features for performing a direct read request from a host device. The resulting system 1080 can perform any of a wide variety of functions, such as memory storage, data processing, and/or other suitable functions. Accordingly, representative systems 1080 can include, without limitation, hand-held devices (e.g., mobile phones, tablets, digital readers, and digital audio players), computers, vehicles, appliances and other products. Components of the system 1080 may be housed in a single unit or distributed over multiple, interconnected units (e.g., through a communications network). The components of the system 1080 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of NAND Flash devices. Apparatuses configured in accordance with other embodiments of the present technology, however, can include other types of suitable storage media in addition to or in lieu of NAND Flash devices, such as, devices incorporating NOR-based non-volatile storage media (e.g., NAND flash), magnetic storage media, phase-change storage media, ferroelectric storage media, dynamic random access memory (DRAM) devices, etc.

The term "processing" as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term "dynamic" as used herein describes processes, functions, actions or implementation occurring during operation, usage, or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

We claim:

1. A method of manufacturing a semiconductor device, the method comprising:
providing a semiconductor substrate having a reference surface opposite a back portion;
forming functional circuitry separated by local trenches on and/or through the reference surface;
etching a marker trench having a target depth deeper than the local trenches on the reference surface;
depositing an oxide material over the reference surface, wherein the oxide material fills the marker trench and forms an oxide layer;
attaching the semiconductor substrate over a carrier wafer, wherein the reference surface faces the carrier wafer and a layer of the oxide is disposed between the semiconductor substrate and the carrier wafer; and
thinning the semiconductor substrate to a thickness matching the target depth based on removing the back portion, wherein the semiconductor substrate is thinned until the oxide within the marker trench is exposed.

2. The method of claim 1, wherein the semiconductor substrate attached over the carrier wafer and having the oxide layer disposed between corresponds to a silicon on insulator (SOI) wafer structure.

3. The method of claim 1, wherein:
etching a marker trench includes etching a set of marker trenches having the target depth; and
depositing the oxide material includes filling the set of marker trenches to form thickness control indicators.

4. The method of claim 3, wherein each of the thickness control indicators have a rectangular footprint or cross-sectional shape.

5. The method of claim 3, wherein the set of marker trenches are arranged encircling a perimeter of the functional circuitry.

6. The method of claim 3, wherein thinning the semiconductor substrate includes establishing a post-thinning surface that is substantially planar, wherein thicknesses measured between the post-thinning surface and the reference surface is within 100 nanometers or less of each other and/or the target thickness.

7. The method of claim 6, wherein the post-thinning thickness of the semiconductor substrate is less than 100 microns.

8. The method of claim 6, wherein thinning the semiconductor includes stopping the thinning process when the oxide within the set of marker trenches is exposed to establish the post-thinning surface that is substantially planar.

9. The method of claim 1, wherein:
the local trenches have a circuit depth;
the functional circuitry is formed within the circuit depth from the reference surface;
the target depth is deeper than the circuit depth;
a remaining silicon remains between a bottom of the local trenches and a post-thinning surface that is established as a result of the thinning; and
further comprising:
forming opposite-side circuits on or through the post-thinning surface and in the remaining silicon.

10. The method of claim 9, wherein:
the semiconductor device is a memory device;
the functional circuitry includes memory cells; and
the opposite-side circuits include access circuitry configured to facilitate access to the memory cells for (1) storing charges in the memory cells during a write and/or (2) detecting an amount of charges stored in the memory cells during a read.

11. The method of claim 10, wherein:
the memory device is a dynamic random-access memory (DRAM) device;
the functional circuitry comprises an array that corresponds to a local grouping of the memory cells;
forming the functional circuitry includes forming multiple memory arrays on the semiconductor substrate;
etching the marker trench includes etching a set of deep trenches for each of the memory arrays,
wherein the set of deep trenches are arranged to encircle the corresponding one of the memory arrays, and
the set of deep trenches have an arrangement and/or a shape that corresponds to a density of filler relative to semiconductive material within a marking area surrounding the corresponding array.

12. The method of claim 1, wherein the marker trench includes a planar bottom portion that corresponds to a trench top opening width and shape.

13. A semiconductor device, comprising:
a bottom semiconductor substrate portion extending laterally;
one or more layers of electrically insulative material over the bottom semiconductor substrate portion;
a top semiconductor substrate portion having a top surface and a bottom surface, the top semiconductor substrate having:
functional circuitry on or closer to the bottom surface than the top surface,
openings extending across a thickness of the top semiconductor substrate; and
filler material in the openings, wherein the filler material is coplanar with the top surface and coplanar with the bottom surface.

14. The semiconductor device of claim 13, wherein the semiconductor device is a dynamic random-access memory (DRAM).

15. The semiconductor device of claim 14, wherein the functional circuitry is an array of memory cells.

16. The semiconductor device of claim 15, wherein the filler material in the openings comprise thickness control mechanisms, wherein the thickness control mechanisms encircle the array.

17. The semiconductor device of claim 13, wherein the top semiconductor substrate portion includes opposite-side circuits on or closer to the top surface than the bottom surface, wherein the opposite-side circuits are above the functional circuitry.

18. The semiconductor device of claim 17, wherein:
the semiconductor device is a dynamic random-access memory (DRAM) device;
the functional circuitry comprises a memory array; and
the opposite-side circuits comprise access circuitry configured to access the memory array for writing data into the memory array and/or reading the data stored in the memory array.

19. The semiconductor device of claim 13, wherein a thickness of the top semiconductor substrate portion, measured between the top and bottom surfaces, is less than 100 microns.

20. The semiconductor device of claim 13, wherein the top semiconductor substrate portion has thicknesses, measured between the top and bottom surfaces, that corresponds to the top surface that is substantially planar, wherein the thicknesses are within 10 nano meters or less of each other.
